(19) United States
(12) Patent Application Publication
(10) Pub. No.: US 2003/0230550 A1
(43) Pub. Date: Dec. 18, 2003

(54) Lithography process

(76) Inventor: Kuang-Yeh Chang, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 10/064,112

(22) Filed: Jun. 12, 2002

(51) Int. Cl. G01L 21/30; G01R 31/00

(52) U.S. Cl. 216/59

(57) ABSTRACT

A lithography process. A substrate is provided first. Then a protective layer is formed on the substrate and a patterned photoresist layer is formed on a surface of the protective layer. A normal lithography process is executed. Finally a first inspection process is performed to screen the correctness of the patterned photoresist layer. When the correctness of the patterned photoresist layer does not fulfill the spec, the patterned photoresist layer on the surface of the protective layer is thereafter removed and the patterned photoresist layer is reformed on the surface of the protective layer.

### BACKGROUND OF INVENTION

1. Field of the Invention

The present invention relates to a lithography process, and more particularly, to a universal lithography re-work process.

2. Description of the Prior Art

Semiconductor chips are manufactured by executing at least tens of lithography processes. To execute a lithography process, the surface of the semiconductor chip is covered with a photoresist layer, and an exposure process is performed using a photomask to project mask patterns onto the photoresist layer. The chemical property of the photoresist layer after exposure is thus changed and a developer is utilized to remove the exposed photoresist or the unexposed photoresist to form the layout patterns corresponding to the mask in the photoresist layer. The residual photoresist layer is removed after some corresponding semiconductor processes to form the expected layout patterns on the semiconductor chip.

With the rapid development of semiconductor processing, the line width has shrunk and the number of masks used is continuously increasing. An accurate lithography process is the key to the remarkable processing ability of a semiconductor manufacturer. The quality of the lithography process depends on the accuracy of the exposure process. Errors during the exposure process can cause the mask patterns to be formed in incorrect locations causing the layout patterns within different layers not to be connected properly. An open circuit or a circuit with poor conductivity is the most common occurrence. To avoid this type of manufacturing defect, alignment marks are formed on the mask so corresponding alignment marks are formed in the photoresist layer after the exposing and developing processes. An after development inspection (ADI) process is thereafter executed by precise instruments to ensure the correctness of the lithography process. Any abnormal wafer is discovered at this stage and is sent to a rework process rather than going to subsequent processes.

Please refer to FIG. 1 and FIG. 2. FIG. 1 is a schematic diagram of performing a lithography process and a rework process on a semiconductor wafer 60 according to the prior art. FIG. 2 is a flowchart 20 of a lithography process and a rework process according to the prior art. As shown in FIG. 1 and FIG. 2, the method for executing a lithography process and a rework process according to the prior art includes the following steps. First, at least one semiconductor wafer 60 is provided (step 30). A silicon substrate 61 is comprised on a surface of the semiconductor wafer 60. At least one deposition layer 62 is comprised on a surface of the silicon substrate 61. The deposition layer 62, being a thin film frequently used in semiconductor process, comprises a silicon dioxide (SiO₂) layer, a silicon nitride (Si₃N₄) layer, a silicon oxynitride (SiOₓN_{y}) layer, a polysilicon layer, or a metal layer.

Then a standard lithography process is performed on the semiconductor wafer 60 (step 32). If the deposition layer 62 is not comprised on the surface of the silicon substrate 61, a patterned photoresist layer 64 formed by the lithography process is used for defining the layout pattern of an ion implantation area or a shallow trench isolation (STI) on the surface of the silicon substrate 61. If the deposition layer 62 is comprised on the surface of the silicon substrate 61, a patterned photoresist layer 64 formed by the lithography process is used for defining the layout pattern of the deposition layer 62. In FIG. 1, the silicon substrate 61 comprising the deposition layer 62 is an example. The layout pattern comprises the pattern of a gate, a via plug, a contact plug, a dual damascence structure, a top plate of a capacitor, a bottom plate of a capacitor, a node contact, a word line, a bit line, a metal line, or a bonding pad depending on the material composition of the deposition layer 62 and the process stage.

It is worth noticing that an anti-reflection coating 66 (ARC) is disposed underneath the bottom of the patterned photoresist layer 64, underneath the bottom of the deposition layer 62, or both. The anti-reflection coating 66 is substantially composed of titanium (Ti), titanium nitride (TiN), titanium tungsten (TiW), or silicon oxynitride, depending on the material composition of the deposition layer 62 and the process requirement. The anti-reflection coating 66 is used for preventing reflections from the surface of the deposition layer 62 during exposure. Hence, the accuracy of the patterned photoresist layer 64 is not decreased.

An after development inspection (ADI) process is thereafter performed (the first ADI process, step 34). The ADI process, being a quality control step, utilizes precise optical equipment and alignment marks (not shown) on the semiconductor wafer 60 to ensure the correctness of the patterned photoresist layer 64, such as the spec for the thickness of the developed photoresist layer, the shape of the patterns, the relative sites, and the sizes of the patterns. If the semiconductor wafer 60 fulfills the spec, a hard bake process is performed to reduce the content of the residue solvent in the photoresist layer as low as possible by evaporation. The standard lithography process (step 32) is thus completed and the next process step is performed (step 42). The next process step could be an etching process or an ion implantation process.

If the semiconductor wafer 60 is out of spec, a plasma ash strip process, utilizing plasma and reactive etching, is performed (step 36) to remove the incorrect patterned photoresist layer 64. After that, a cleaning and rinsing process is performed (step 38) to remove the ash-formed photoresist layer, the polymer residue, particles, and metal contamination remaining on the surface of the semiconductor wafer 60. A fluorine based solvent, an amine based solvent, or at least one chemical is first utilized to perform a wet cleaning process. A rinsing process and a drying process are thereafter performed.

An inspection process after cleaning is performed (step 40) to ensure the cleanness of the semiconductor wafer 60. In a semiconductor production line, the specs for various products and various process stages are established. Therefore when the size and the quantity of the photoresist layer, the polymer residue, particles, metal contamination, and the micro roughness remaining on the surface of the semiconductor wafer 60 fulfill the spec, the cleaning and rinsing process is completed and the semiconductor wafer 60 is sent back to the standard lithography process (step 32).

Similarly to a new wafer, an ADI process is performed on a reworked wafer after the patterned photoresist layer 64 is reformed (the ADI process, step 34, performed a second time) to ensure the correctness of the patterned photoresist layer 64. If the semiconductor wafer 60 fulfills the spec, the subsequent processes are performed as described before. If the semiconductor wafer 60 does not fulfill the spec, the semiconductor wafer 60 is sent back to the plasma ash strip process step (step 36). The photoresist is removed again by utilizing plasma and reactive etching. After that, the subsequent processes are performed as described before.

The plasma ash strip process (step 36), the cleaning and rinsing process (step 38), the inspection process after cleaning (step 40), the standard lithography process (step 32), and the second ADI process (step 34) is the whole of the rework process.

The flowchart 20 of a lithography process and a rework process according to the prior art comprises the following steps:

Step 30:Provide at least one semiconductor wafer;

Step 32:Perform a standard lithography process to the semiconductor wafer;

Step 34:Perform an ADI process, if the semiconductor wafer fulfills the spec, go to step 42; if the semiconductor wafer does not fulfill the spec, go to step 36;

Step 36:Perform a plasma ash strip process;

Step 38:Perform a cleaning and rinsing process;

Step 40:Perform an inspection process after cleaning, if the semiconductor wafer fulfills the spec, go to step 32; if the semiconductor wafer does not fulfill the spec, go to step 36; and

Step 42:Perform the next process step.

The incorrectly patterned photoresist layer is removed and a correct patterned photoresist layer is reformed with the addition of several processing steps by executing the lithography process and the rework process according to the prior art. Problems, such as junction leakage current lifting, bridge, decreased yield, decreased oxide breakdown voltage, and change of threshold voltage of a metal-oxide semiconductor, are also avoided due to sufficient cleanness of the surface of the semiconductor wafer. However, with the consideration of forming a correct patterned photoresist layer and ensuring the cleanness, it is frequently observed that the surface of the semiconductor wafer is changed or damaged after the plasma ash strip process and the cleaning and rinsing process. The poor photoresist adhesion problem during a subsequent lithography process, the profile change problem, and the fall down problem occur this way making a rework process difficult or unfeasible.

### SUMMARY OF INVENTION

It is therefore a primary objective of the claimed invention to provide a lithography process and method to resolve the above-mentioned problem, and to reduce the quantity of the scrap semiconductor wafers due to a rework process.

According to the claimed invention, a substrate is provided first. Then a protective layer is formed on a surface of the substrate. A patterned photoresist layer is thereafter formed on a surface of the protective layer. Finally, a first inspection process is performed to screen the correctness of the patterned photoresist layer. When the correctness of the patterned photoresist layer fulfills the spec, a normal process is performed to the substrate. When the correctness of the patterned photoresist layer does not fulfill the spec, the patterned photoresist layer on the surface of the protective layer is removed and the patterned photoresist layer is reformed on the surface of the protective layer by a rework process.

It is an advantage of the claimed invention to perform a lithography process and a rework process by forming a very thin protective layer on the surface of the semiconductor wafer, which will not disturb the subsequent etching process and ion implantation process, then perform the lithography process. When the correctness of the patterned photoresist layer does not fulfill the spec, the rework process for reforming a correct patterned photoresist layer does not affect the cleanness and the quality of the surface of the semiconductor wafer. When the correctness of the patterned photoresist layer fulfills the spec, the very thin protective layer does not affect subsequent normal processing. In summary, the production yield is raised and the quantity of scrap wafers incurred from the rework process is reduced when applying the claimed invention method to the production line.

These and other objectives of the claimed invention will no doubt become obvious to those of ordinary skill in the art after reading the following detailed description of the preferred embodiment, which is illustrated in the various figures and drawings.

### BRIEF DESCRIPTION OF DRAWINGS

FIG. 1 is a schematic diagram of performing a lithography process and a rework process on a semiconductor wafer according to the prior art.

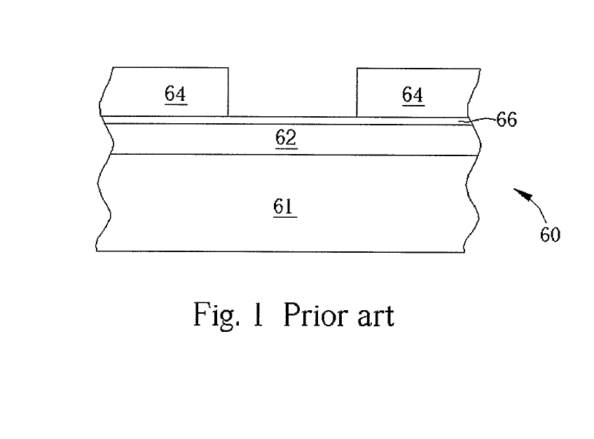

FIG. 2 is a flowchart of a lithography process and a rework process according to the prior art.

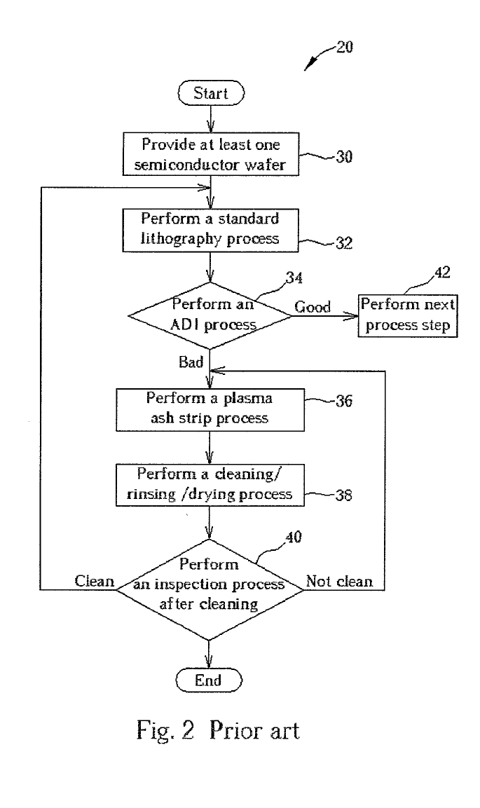

FIG. 3 is a schematic diagram of performing a lithography process and a rework process on a semiconductor wafer according to the present invention.

FIG. 4 is a flowchart of a lithography process and a rework process according to the present invention.

### DETAILED DESCRIPTION

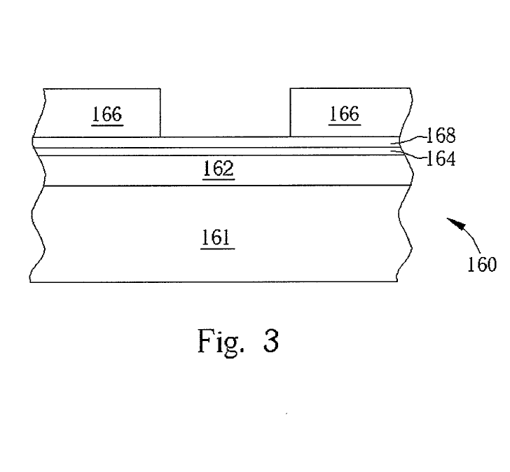

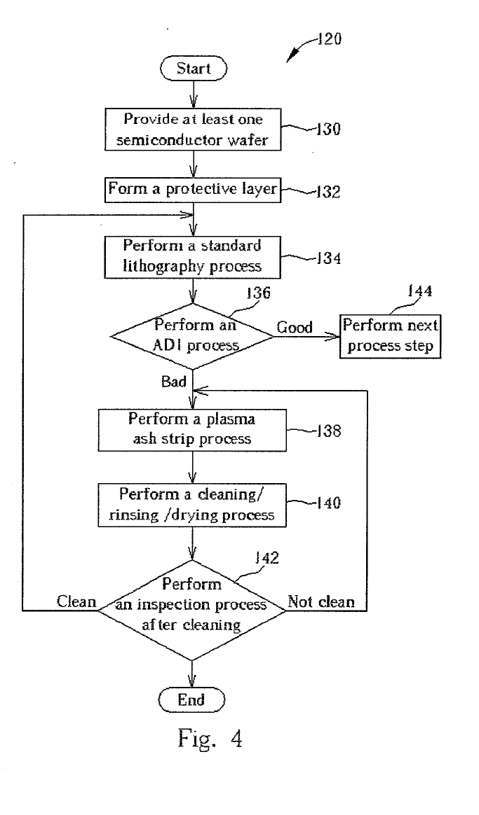

Please refer to FIG. 3 and FIG. 4. FIG. 3 is a schematic diagram of performing a lithography process and a rework process on a semiconductor wafer 160 according to the present invention. FIG. 4 is a flowchart 120 of a lithography process and a rework process according to the present invention. As shown in FIG. 3 and FIG. 4, the method for executing a lithography process and a rework process according to the present invention includes the following steps. Firstly at least one semiconductor wafer 160 is provided (step 130). A silicon substrate 161 is comprised on a surface of the semiconductor wafer 160. At least one deposition layer 162 is further comprised on a surface of the silicon substrate 161. The deposition layer 162, being a thin film frequently used in semiconductor process, comprises a silicon dioxide (SiO₂) layer, a silicon nitride (Si₃N₄) layer, a silicon oxynitride (SiOₓN_{y}) layer, a polysilicon or a metal layer.

Then a protective layer 164 is formed on the surface of the semiconductor wafer 160 (step 132). The protective layer 164 is a silicon oxide layer, a tetra-ethyl-orthosilicate (TEOS) layer, or other dielectric layer having a thickness of approximately 50 Å. If the protective layer 164 is a silicon oxide layer or a tetra-ethyl-ortho-silicate layer, the protective layer 164 is formed by a low pressure chemical vapor deposition (LPCVD) process or a plasma enhanced chemical vapor deposition (PECVD) process.

When considering the material composition of the protective layer 164, it is necessary that the surface property of the protective layer 164 will not change during a plasma ash strip process or a cleaning and rinsing process. In addition, the thickness of the protective layer 164 needs to be very thin so the subsequent etching and ion implantation processes are not disturbed.

A standard lithography process is performed to the semiconductor wafer 160 (step 134). If the deposition layer is not comprised on the surface of the silicon substrate 161, a patterned photoresist layer 166 formed by the lithography process is used for defining the layout pattern of an ion implantation area or a shallow trench isolation (STI) on the surface of the silicon substrate 161. If the deposition layer 162 is comprised on the surface of the silicon substrate 161, a patterned photoresist layer 166 formed by the lithography process is used for defining the layout pattern of the deposition layer 162.

In FIG. 3, the silicon substrate 161 comprising the deposition layer 162 is an example. The layout pattern comprises the pattern of a gate, a via plug, a contact plug, a dual damascence structure, a top plate of a capacitor, a bottom plate of a capacitor, a node contact, a word line, a bit line, a metal line, or a bonding pad depending on the material composition of the deposition layer 162 and the process objective.

It is worth noticing that an anti-reflection coating 168 is disposed underneath the bottom of the patterned photoresist layer 166, underneath the bottom of the deposition layer 162, or both. The anti-reflection coating 168 is substantially composed of titanium (Ti), titanium nitride (TiN), titanium tungsten (TiW), or silicon oxynitride depending on the material composition of the deposition layer 162 and the process requirement. The anti-reflection coating 168 is used for preventing reflections from the surface of the deposition layer 162 during exposure. Hence, the accuracy for the patterned photoresist layer 166 is not decreased.

An after development inspection (ADI) process is thereafter performed (the first ADI process, step 136). The ADI process, being a quality control step, utilizes precise optical equipment and alignment marks (not shown) on the semiconductor wafer 160 so as to ensure the correctness of the patterned photoresist layer 166, such as the spec for the thickness of the developed photoresist layer, the shape of the patterns, the relative sites, and the sizes of the patterns. If the semiconductor wafer 160 fulfills the spec, a hard bake process is performed to reduce the content of the residue solvent in the photoresist layer as low as possible by evaporation. The standard lithography process (step 134) is thus completed and the next process step is performed(step 144). The next process step could be an etching process or an ion implantation process. Since the protective layer 164 is very thin, the subsequent etching process or ion implantation process is not disturbed. The protective layer 164 may be or may not be removed after completing the next process step, depending on the device structure, the device category, and the process requirement.

If the semiconductor wafer 160 is out of spec, a plasma ash strip process, utilizing plasma and reactive etching, is performed (step 138) to remove the incorrect patterned photoresist layer 166. After that, a cleaning and rinsing process is performed (step 140) to remove the ash-formed photoresist layer, the polymer residue, particles, and metal contamination remaining on the surface of the semiconductor wafer 160. A fluorine based solvent, an amine based solvent, or at least one chemical is first utilized to perform a wet cleaning process. A rinsing process and a drying process are thereafter performed. Since the material composition of the protective layer 164 is compatible with the plasma ash strip process and the cleaning and rinsing process, the surface property of the protective layer 164 will not change during these processes. Hence, the protective layer 164 is able to protect the surface of the semiconductor wafer 160 from problems such as poor photoresist adhesion during a subsequent lithography process, a profile change, and fall down.

An inspection process after cleaning is performed (step 142) to ensure the cleanness of the semiconductor wafer 160. In semiconductor production line, the specs for various products and various process stages are established. Therefore, when the size and the quantity of the photoresist layer, the polymer residue, particles, metal contamination, and the micro roughness remaining on the surface of the semiconductor wafer 160 fulfill the spec, the cleaning and rinsing process is completed and the semiconductor wafer 160 is sent back to the standard lithography process (step 134).

An ADI process is performed after the patterned photoresist layer 166 is reformed (the ADI process, step 136, performed a second time) to ensure the correctness of the patterned photoresist layer 166. After that, the subsequent processes are performed as described before. If the semiconductor wafer 160 does not fulfill the spec, the semiconductor wafer 160 is sent back to the plasma ash strip process step (step 138). The photoresist layer 166 is removed again by utilizing plasma and reactive etching. Next, the subsequent processes are performed as described before.

The plasma ash strip process (step 138), the cleaning and rinsing process (step 140), the inspection process after cleaning (step 142), the standard lithography process (step 144), and the second ADI process (step 136) is the whole of the rework process.

The flowchart 120 of a lithography process and a rework process according to the present invention comprises the following steps:

Step 130:Provide at least one semiconductor wafer;

Step 132:Form a protective layer on the surface of the semiconductor wafer;

Step 134:Perform a standard lithography process to the semiconductor wafer;

Step 136:Perform an ADI process, if the semiconductor wafer fulfills the spec, go to step 144; if the semiconductor wafer does not fulfill the spec, go to step 138;

Step 138:Perform a plasma ash strip process;

Step 140:Perform a cleaning and rinsing process;

Step 142:Perform an inspection process after cleaning, if the semiconductor wafer fulfills the spec, go to step 134; if the semiconductor wafer does not fulfill the spec, go to step 138; and

Step 144:Perform the next process step.

The method of performing a lithography process and a rework process according to the present invention is to form a very thin protective layer, which will not disturb the subsequent etching process and ion implantation process, on the surface of the semiconductor wafer, then perform the lithography process. When the correctness of the patterned photoresist layer does not fulfill the spec, the rework process for reforming a correct patterned photoresist layer does not affect the cleanness and the quality of the surface of the semiconductor wafer. When the correctness of the patterned photoresist layer fulfills the spec, the very thin protective layer does not affect the subsequent normal processes.

In contrast to the prior art method of performing a lithography process and a rework process, the present invention method is to form a very thin protective layer on the surface of the semiconductor wafer, then perform the lithography process and the rework process. Since the protective layer is very thin, it will not disturb the subsequent etching process or ion implantation process. Under this premise, a correct patterned photoresist layer is reformed with the addition of several process steps and the surface of the semiconductor wafer sufficiently clean. In addition, the surface condition of the protective layer does not change due to the plasma ash strip process and the cleaning and rinsing process. The protective layer therefore effectively protects the surface structure of the semiconductor wafer to avoid the poor photoresist adhesion problem during subsequent lithography process, the profile change problem, and the fall down problem. The feasibility for rework process is greatly enhanced. In summary, the production yield is raised and the quantity of scrap wafers incurred from rework process is reduced when applying the present invention method to the production line.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. A lithography process comprising:
providing a substrate;
forming a protective layer on a surface of the substrate;
forming a patterned photoresist layer on a surface of the protective layer; and
performing a first inspection process.

2. The process of claim 1 wherein the substrate is a semiconductor wafer, and the semiconductor wafer comprises a silicon substrate.

3. The process of claim 2 wherein the patterned photoresist layer is used for defining the layout pattern of an ion implantation area or a shallow trench isolation (STI) on a surface of the silicon substrate.

4. The process of claim 2 wherein the surface of the semiconductor wafer further comprises at least one deposition layer, the patterned photoresist layer is used for defining the layout pattern of the deposition layer.

5. The process of claim 4 wherein the deposition layer comprises a silicon dioxide (SiO₂) layer, a silicon nitride (Si₃N₄) layer, a silicon oxynitride (SiOₓN_{y}) layer, a polysilicon layer, or a metal layer.

6. The process of claim 4 wherein the layout pattern comprises the pattern of a gate, a via plug, a contact plug, a dual damascence structure, a top plate of a capacitor, a bottom plate of a capacitor, a node contact, a word line, a bit line, a metal line, or a bonding pad.

7. The process of claim 1 wherein an anti-reflection coating (ARC) is disposed underneath the bottom of the patterned photoresist layer.

8. The process of claim 1 wherein the protective layer is a dielectric layer with a thickness of not more than 50 Å.

9. The process of claim 8 wherein the material composition of the dielectric layer comprises silicon oxide compound or tetra-ethyl-ortho-silicate SiO₂ (TEOS-SiO₂).

10. The process of claim 8 wherein the method of forming the protective layer comprises a low pressure chemical vapor deposition (LPCVD) process or a plasma enhanced chemical vapor deposition (PECVD) process.

11. The process of claim 1 wherein the first inspection process is an after develop inspection (ADI) process to screen the correctness of the patterned photoresist layer.

12. The process of claim II wherein when the correctness of the patterned photoresist layer fulfills the spec, a normal process is performed, when the correctness of the patterned photoresist layer does not fulfill the spec, a rework process is performed.

13. The process of claim 12 wherein the normal process comprises an etching process or an ion implantation process.

14. The process of claim 12 wherein the rework process comprises the following steps:
performing a plasma ashing process to remove the patterned photoresist layer on the surface of the protective layer;
performing a wet cleaning process;
performing a rinsing process and a dry process;
performing a second inspection process;
reforming the patterned photoresist layer on the surface of the protective layer; and
performing a third inspection process.

15. The process of claim 14 wherein a fluorine based solvent, an amine based solvent, or at least one chemical is utilized in the wet cleaning process to remove the photoresist layer, polymer residue, particles, and metal contamination remaining on the surface of the substrate.

16. The process of claim 14 wherein the second inspection process is an inspection process after cleaning to inspect the cleanness of the surface of the substrate.

17. The process of claim 14 wherein the third inspection process is an after develop inspection (ADI) process to screen the correctness of the reformed patterned photoresist layer.

18. A lithography process comprising:
providing a substrate, a surface of the substrate comprising at least one deposition layer;
forming a protective layer on a surface of the deposition layer;
forming a patterned photoresist layer on a surface of the protective layer to define the layout pattern of the deposition layer; and
performing a first inspection process.

19. The process of claim 18 wherein the substrate is a semiconductor wafer, and the deposition layer comprises a silicon dioxide (SiO₂) layer, a silicon nitride (Si₃N₄) layer, a silicon oxynitride (SiOₓN_{y}) layer, a polysilicon layer, or a metal layer.

20. The process of claim 18 wherein the layout pattern comprises the pattern of a gate, a via plug, a contact plug, a dual damascence structure, a top plate of a capacitor, a bottom plate of a capacitor, a node contact, a word line, a bit line, a metal line, or a bonding pad.

21. The process of claim 18 wherein an anti-reflection coating (ARC) is disposed underneath the bottom of the patterned photoresist layer.

22. The process of claim 18 wherein the protective layer is dielectric layer with a thickness of not more than 50 Å.

23. The process of claim 22 wherein the material composition of the dielectric layer comprises silicon oxide compound or tetra-ethyl-ortho-silicate SiO₂ (TEOS-SiO₂), and the method of forming the dielectric layer comprises a low pressure chemical vapor depostion (LPCVD) process or a plasma enhanced chemical vapor deposition (PECVD) process.

24. The process of claim 18 wherein the first inspection process is an after develop inspection (ADI) process to screen the correctness of the patterned photoresist layer.

25. The process of claim 24 wherein when the correctness of the patterned photoresist layer fulfills the spec, an etching process is performed to transfer the layout pattern of the patterned photoresist layer to the deposition layer, when the correctness of the patterned photoresist layer does not fulfill the spec, a rework process is performed.

26. The process of claim 25 wherein the rework process comprises the following steps:
performing a plasma ashing process to remove the patterned photoresist layer on the surface of the protective layer;
performing a wet cleaning process;
performing a rinsing process and a dry process;
performing a second inspection process;
reforming the patterned photoresist layer on the protective layer; and
performing a third inspection process.

27. The process of claim 26 wherein a fluorine based solvent, an amine based solvent, or at least one chemical is utilized in the wet cleaning process to remove the photoresist layer, polymer residue, particles, and metal contamination remaining on the surface of the substrate.

28. The process of claim 26 wherein the second inspection process is an inspection process after cleaning to inspect the cleanness of the surface of the substrate.

29. The process of claim 26 wherein the third inspection process is an after develop inspection (ADI) process to screen the correctness of the reformed patterned photoresist layer.

30. A reworkable lithography process comprising:
providing a substrate;
forming a protective layer on a surface of the deposition layer;
forming a patterned photoresist layer on a surface of the protective layer; and performing a first after develop inspection (ADI) process to screen the correctness of the patterned photoresist layer;
wherein when the correctness of the patterned photoresist layer fulfills the spec, a normal process is performed, when the correctness of the patterned photoresist layer does not fulfill the spec, a rework process is performed by utilizing the protective layer to protect the surface of the substrate.

31. The process of claim 30 wherein the substrate is a semiconductor wafer, and the semiconductor wafer comprises a silicon substrate.

32. The process of claim 30 wherein the patterned photoresist layer is used for defining the layout pattern of an ion implantation area or a shallow trench isolation (STI) on a surface of the silicon substrate.

33. The process of claim 30 wherein the surface of the semiconductor wafer further comprises at least one deposition layer, the patterned photoresist layer is used for defining the layout pattern of the deposition layer.

34. The process of claim 33 wherein the deposition layer comprises a silicon dioxide (SiO₂) layer, a silicon nitride (Si₃N₄) layer, a silicon oxynitride (SiOₓN_{y}) layer, a polysilicon layer, or a metal layer.

35. The process of claim 33 wherein the layout pattern comprises the pattern of a gate, a via plug, a contact plug, a dual damascence structure, a top plate of a capacitor, a bottom plate of a capacitor, a node contact, a word line, a bit line, a metal line, or a bonding pad.

36. The process of claim 30 wherein an anti-reflection coating (ARC) is disposed underneath the bottom of the patterned photoresist layer.

37. The process of claim 30 wherein the protective layer is a dielectric layer with a thickness of not more than 50 Å.

38. The process of claim 37 wherein the material composition of the dielectric layer comprises silicon oxide compound or tetra-ethyl-ortho-silicate SiO₂ (TEOS-SiO₂), and the method of forming the dielectric layer comprises a low pressure chemical vapor depostion (LPCVD) process or a plasma enhanced chemical vapor deposition (PECVD) process.

39. The process of claim 30 wherein the normal process comprises an etching process or an ion implantation process.

40. The process of claim 30 wherein the rework process comprises the following steps:
performing a plasma ashing process to remove the patterned photoresist layer on the surface of the protective layer;
performing a wet cleaning process;
performing a rinsing process and a dry process;
performing an inspection process after cleaning to inspect the cleanness of the surface of the substrate;
reforming the patterned photoresist layer on the surface of the protective layer; and
performing a second after develop inspection (ADI) process to screen the correctness of the reformed patterned photoresist layer.

41. The process of claim 40 wherein a fluorine based solvent, an amine based solvent, or at least one chemical is utilized in the wet cleaning process to remove the photoresist layer, polymer residue, particles, and metal contamination remaining on the surface of the substrate.

42. The process of claim 40 wherein when the correctness of the reformed patterned photoresist layer fulfills the spec, a normal process is performed, when the correctness of the reformed patterned photoresist layer does not fulfill the spec, a rework process is performed by utilizing the protective layer to protect the surface of the substrate.
